(19) United States
(12) Patent Application Publication
(10) Pub. No.: US 2026/0029428 A1
(43) Pub. Date: Jan. 29, 2026

(54) PROBE AND METHOD FOR MANUFACTURING ELECTRICAL CONNECTION DEVICE

(71) Applicant: Kabushiki Kaisha Nihon Micronics, Tokyo (JP)

(72) Inventors: Toshinaga TAKEYA, Aomori (JP); Yasutaka KISHI, Aomori (JP)

(21) Appl. No.: 19/343,240

(22) Filed: Sep. 29, 2025

Related U.S. Application Data
(63) Continuation of application No. PCT/JP2024/001484, filed on Jan. 19, 2024.

(30) Foreign Application Priority Data
Apr. 3, 2023 (JP) 2023-060072

(51) Int. Cl. G01R 1/067

(52) U.S. Cl. CPC G01R 1/06716; G01R 1/06733

(57) ABSTRACT

A probe includes an arm portion with a contact portion at a tip of a free end protruding in a first direction in a cantilever structure; a support portion connected to the arm portion; a joint portion connected to the support portion; and a tension generating section. The tension generating section includes a first end connected to the support portion, and a second end located closer to the contact portion than the first end in the first direction, and that is separated from the support portion. The tension generating section is elastically deformable so that the position of the second end varies in the first direction.

### CROSS-REFERENCE TO RELATED APPLICATIONS

The present application is a continuation of International Application No. PCT/JP2024/001484, filed on Jan. 19, 2024, and based upon and claims the benefit of priority from Japanese Patent Application No. 2023-060072, filed on Apr. 3, 2023, the entire contents of which are incorporated herein by reference.

### TECHNICAL FIELD

The present application relates to a probe used for inspection of an object to be inspected, and a method of manufacturing an electrical connection device.

### BACKGROUND ART

An electrical connection device including a probe is used for inspection of an object to be inspected, such as an integrated circuit, and the probe is brought into contact with the object to be inspected. During inspection using the electrical connection device, one end of the probe is brought into contact with an electrode terminal of the object to be inspected. The other end of the probe is electrically connected to a wiring pattern arranged on a circuit board of the electrical connection device. The wiring pattern is electrically connected to an inspection device such as a multimeter. Electrical signals can be transmitted and received between the object to be inspected and the inspection device through the probe.

### SUMMARY

In a configuration of an electrical connection device, a probe is attached to a circuit board such as an interposer board. In order to accurately inspect an object to be inspected, it is necessary to join a plurality of probes to the circuit board in such a manner that positions of contact portions of the probes that come into contact with the object to be inspected are aligned with high accuracy. However, if the circuit board is warped or distorted, the positions of the contact portions between the probes may vary.

An object of the present application is to provide a probe that can be attached to a circuit board with a contact portion position aligned to contact an object to be inspected.

A probe according to an embodiment includes an arm portion with a contact portion at a tip of a free end protruding in a first direction in a cantilever structure; a support portion connected to the arm portion; a joint portion connected to the support portion; and a tension generating section. The tension generating section includes a first end connected to the support portion, and a second end located closer to the contact portion than the first end in the first direction, and that is separated from the support portion. The tension generating section is elastically deformable so that the position of the second end varies in the first direction.

According to the embodiment, it is possible to provide a probe which can be attached to a circuit board while aligning positions of contact portions that are brought into contact with an object to be inspected.

### BRIEF DESCRIPTION OF DRAWINGS

FIG. 1 is a schematic front view illustrating a configuration of a probe according to an embodiment.

FIG. 2 is a schematic side view illustrating a configuration of the probe according to the embodiment.

FIG. 3 is a schematic view illustrating a state in which the probe according to the embodiment is stored in a guide plate.

FIG. 4 is a flowchart for explaining a method of joining the probe held in a guide plate to a circuit board.

FIG. 5 is a schematic view for explaining a method of joining the probe held in a guide plate to a circuit board (Part 1).

FIG. 6 is a schematic view for explaining a method of joining the probe held in a guide plate to a circuit board (Part 2).

FIG. 7 is a schematic diagram illustrating an example of a shape of a second end of a tension generating section of the probe according to the embodiment.

FIG. 8 is a schematic diagram illustrating another example of the shape of the second end of the tension generating section of the probe according to the embodiment.

### DESCRIPTION OF EMBODIMENTS

Next, an embodiment will be described with reference to the drawings. In the description of the following drawings, the same or similar parts are denoted by the same or similar reference signs. However, it should be noted that the drawings are schematic, and the thickness ratio of parts is different from the actual one. Moreover, there are parts in which dimensional relationships and proportions differ among the drawings. The following embodiments exemplify a device and a method realizing technical concepts of the present invention, and the embodiment does not specify a material, shape, structure, arrangement, or the like, of components as described below.

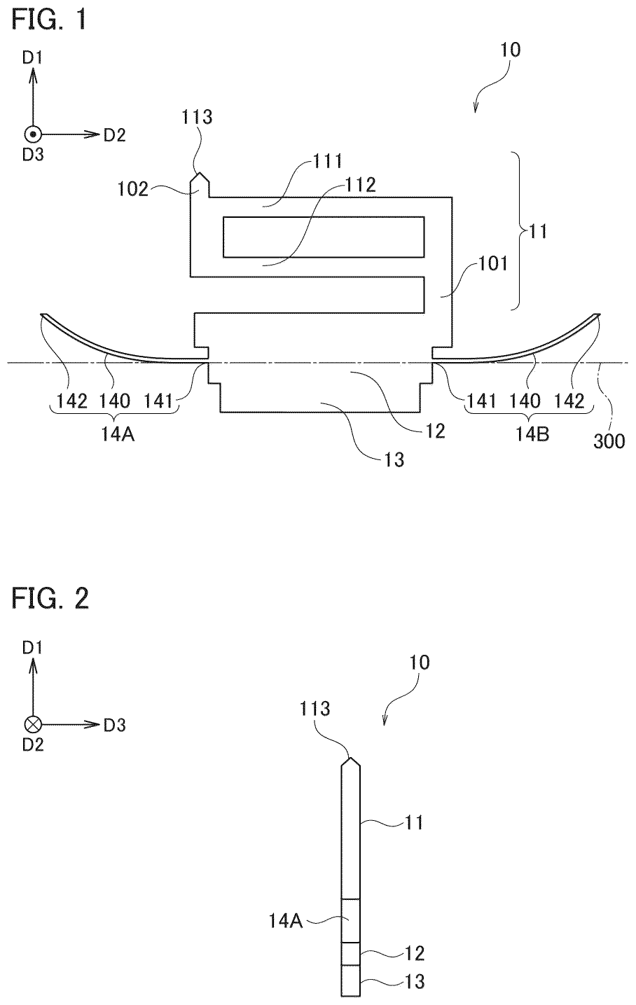

FIGS. 1 and 2 illustrate a probe 10 according to an embodiment. The probe 10 is used for inspection of electrical characteristics of an object to be inspected. The probe 10 includes an arm portion 11 including a fixed end 101 and a free end 102 in a cantilever structure, a support portion 12 connected to the arm portion 11 at the fixed end 101, and a joint portion 13 connected to the support portion 12 at a region separated from a region connected to the fixed end 101. The joint portion 13, the support portion 12, and the arm portion 11 are connected in a first direction D1, in this order. A contact portion 113 at a tip of the free end 102 of the arm portion 11 projects in the first direction D1. The contact portion 113 comes into contact with the object to be inspected.

As described above, the contact portion 113 is located in the first direction D1 when viewed from the joint portion 13. As illustrated in FIG. 1, the fixed end 101 is located in a second direction D2 perpendicular to the first direction D1 when viewed from the free end 102 of the arm portion 11. A third direction D3 is perpendicular to a plane defined by the first direction D1 and the second direction D2. In FIG. 1, the first direction D1 is a vertical direction with respect to the plane of the drawing, the second direction D2 is a horizontal direction with respect to the plain of the drawing, and the third direction D3 is into and out of the page with respect to the plain of the drawing. A drawing viewed in the third direction D3 is a front view, and a drawing viewed in the second direction D2 is a side view.

The probe 10 further includes a first tension generating section 14A and a second tension generating section 14B, which are connected to the support portion 12 and extend in the second direction D2 from the support portion 12. The first tension generating section 14A extends in a direction from the fixed end 101 of the arm portion 11 to the free end 102. The second tension generating section 14B extends in a direction from the free end 102 of the arm portion 11 to the fixed end 101. Hereinafter, the first tension generating section 14A and the second tension generating section 14B will be referred to as a tension generating section 14 when an explanation is not limited to one or the other.

The tension generating section 14 includes a body 140, a first end 141 which is one end of the body 140, and a second end 142 which is another end of the body 140. The first end 141 is connected to the support portion 12, and the second end 142 is a free end located in a position separated from the support portion 12.

The second end 142 of the tension generating section 14 is located closer to the contact portion 113 than the first end 141 in the first direction D1. That is, as illustrated in FIG. 1, when a virtual surface 300 is assumed to be on the same plane level as the first end 141 and perpendicular to the first direction D1, the second end 142 is located in the first direction D1 with respect to the virtual surface 300. For example, the second end 142 may be located on the same plane level as a boundary between the arm portion 11 and the support portion 12, or may be located closer to the contact portion 113 than the boundary between the arm portion 11 and the support portion 12.

The body 140 of the tension generating section 14 is flexible enough to be elastically deformable so that the position of the second end 142 varies in the first direction D1. For example, the tension generating section 14 may be in the shape of a plate having a length in the third direction D3 (hereinafter referred to as “width”) longer than a length in the first direction D1 (hereinafter referred to as “thickness”). The probe 10 used for inspecting the electrical characteristics of an object to be inspected includes an electrically conductive material, and the thickness of the tension generating section 14 is configured to deform in the first direction D1. The width of the tension generating section 14 may be approximately the same as the width of the support portion 12.

The tension generating section 14 illustrated in FIG. 1 has a curved shape when viewed in the third direction D3. That is, the tension generating section 14 may be in the shape of an arc bulging in the first direction D1. Alternatively, the tension generating section 14 may be in the shape of a straight line when viewed in the third direction D3, or may be in the shape of a combination of a straight line and a curve. In other words, any shape of the tension generating section 14 can be selected as long as the tension generating section 14 is elastically deformable in the first direction D1.

Any configuration of the arm portion 11 is possible as long as the contact portion 113 projects in the first direction D1. As illustrated in FIG. 1, the arm portion 11 of the probe 10 includes a first arm 111 and a second arm 112 arranged between the fixed end 101 and the free end 102, in parallel and spaced apart from each other in the first direction D1. An end of the first arm 111 and an end of the second arm 112 are connected at each of the fixed end 101 and the free end 102. The first arm 111 is located closer to the contact portion 113 than the second arm 112, and the second arm 112 is located farther from the contact portion 113, and closer to the support portion 12, than the first arm 111.

The probe 10 is attached to a circuit board such as an interposer substrate, and constitutes a part of an electrical connection device. For the inspection of an object to be inspected using the electrical connection device, the contact portion 113 of the probe 10 is brought into contact with an electrode terminal of the object to be inspected. In the electrical connection device, the joint portion 13 of the probe 10 is electrically connected to a wiring pattern arranged on the circuit board. The wiring pattern of the circuit board is electrically connected to an inspection device, such as a multimeter. Therefore, in the inspection using the electrical connection device, electrical signals can be transmitted and received between the object to be inspected and the inspection device through the probe 10 and the circuit board. A material with high electrical conductivity, such as metal, is used for the probe 10 to which the electrical signals propagate.

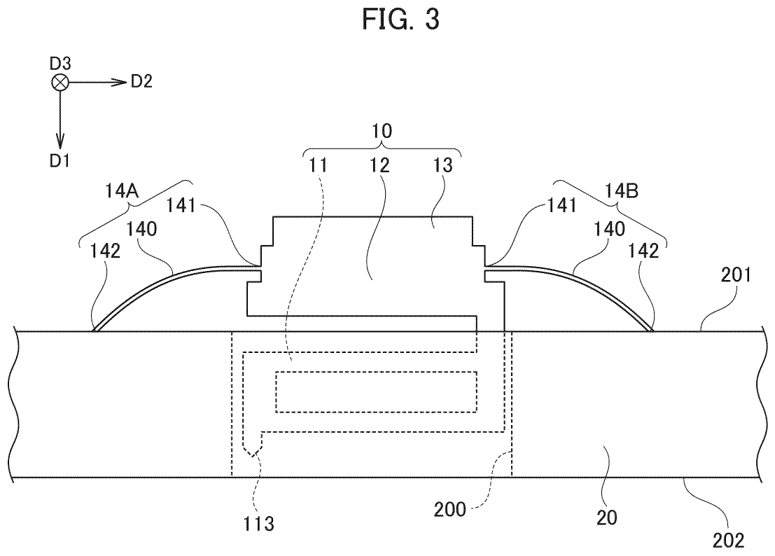

The probe 10 is joined to the circuit board while being held by a guide plate 20, as illustrated in FIG. 3. The probe 10 is held by the guide plate 20 while being inserted into a through hole 200 that penetrates the guide plate 20 from a first main surface 201 to a second main surface 202 facing in a direction opposite to the first main surface 201. The probe 10 has a shape in which the joint portion 13 is exposed outside the guide plate 20 while being held by the guide plate 20. That is, the joint portion 13 is exposed outside the guide plate 20 with the arm portion 11 being inserted into the through hole 200 penetrating the guide plate 20. At this point, the second end 142 of the tension generating section 14 contacts the first main surface 201 of the guide plate 20 in which the through hole 200 is formed. The shape of the tension generating section 14 is provided so that pressure is applied by the tension generating section 14 to the first main surface 201 with the second end 142 contacting the first main surface 201.

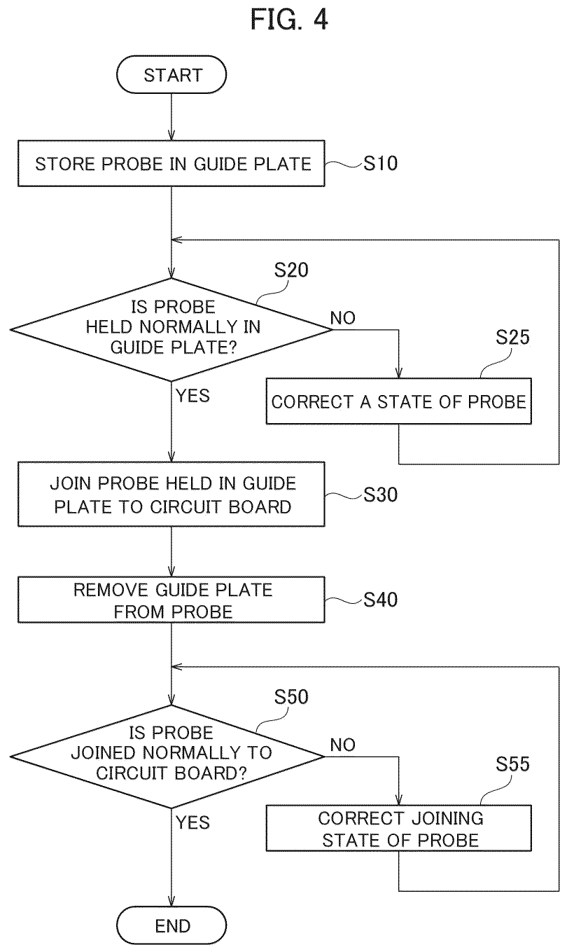

Referring to FIG. 4, an example of a method of manufacturing the electrical connection device by attaching the probe 10 to a circuit board will be described below.

First, as illustrated in FIG. 3, for example, the guide plate 20 including the through hole 200 is prepared. Then, in step S10 of FIG. 4, the probe 10 is stored in the guide plate 20. That is, as illustrated in FIG. 3, the probe 10 is inserted into the through hole 200 of the guide plate 20. The probe 10 is held in the guide plate 20 so that the joint portion 13 is exposed outside the guide plate 20, and the second end 142 of the tension generating section 14 contacts the guide plate 20. For example, side faces of the probe 10 are held by the guide plate 20. With the probe 10 held by the guide plate 20, the second end 142 of the tension generating section 14 contacts the first main surface 201.

When the probe 10 held in the guide plate 20 is joined to a circuit board to manufacture the electrical connection device, the probe 10 is required to be held normally in the guide plate 20. “Held normally” means that the probe 10 is inserted straight into the through hole 200 to a predetermined position. Therefore, after the probe 10 is stored in the guide plate 20, in step S20 in FIG. 4, it is checked whether the probe 10 is held normally in the guide plate 20. If the probe 10 is held normally in the guide plate 20, the process proceeds to step S30. However, if the probe 10 is not held normally in the guide plate 20, the process proceeds to step S25, in which the position and orientation of the probe 10 are corrected so that the probe 10 is inserted straight into the through hole 200 to a predetermined position.

In step S30, the probe 10 held in the guide plate 20 is joined to the circuit board. At this point, the probe 10 is brought close to a circuit board 30 in the first direction D1, and the joint portion 13 of the probe 10 is brought into contact with the circuit board 30. If the circuit board 30 is warped or distorted, the distance between the joint portion 13 of the probe 10 held in the guide plate 20 and the circuit board 30 varies depending on the position of the probe 10 in the circuit board 30. Therefore, the pressure applied by the tension generating section 14 to the guide plate 20 differs for each probe 10, and for example, the magnitude of deformation of the tension generating section 14 differs for each probe 10.

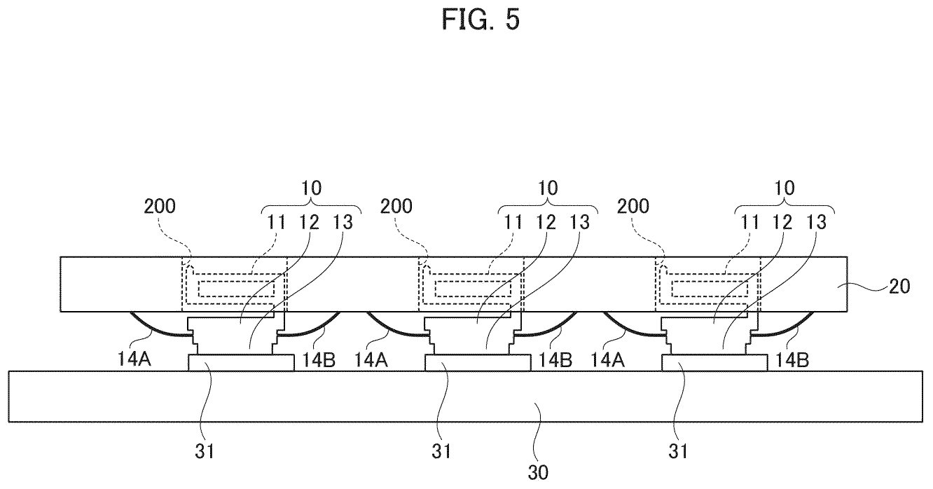

Any method can be selected for joining the probe 10 to the circuit board 30. For example, as illustrated in FIG. 5, a joint material 31 with electrical conductivity, such as solder, is applied to a predetermined joint region of the circuit board 30, and the joint portion 13 of the probe 10 is joined to the circuit board 30 by the joint material 31. The probe 10 is electrically connected to a wiring pattern (not illustrated) of the circuit board 30. When solder is used for the joint material 31, a residual stress inside the solder may be removed by slowly cooling aging after reflow soldering for joining the probe 10 to the circuit board 30.

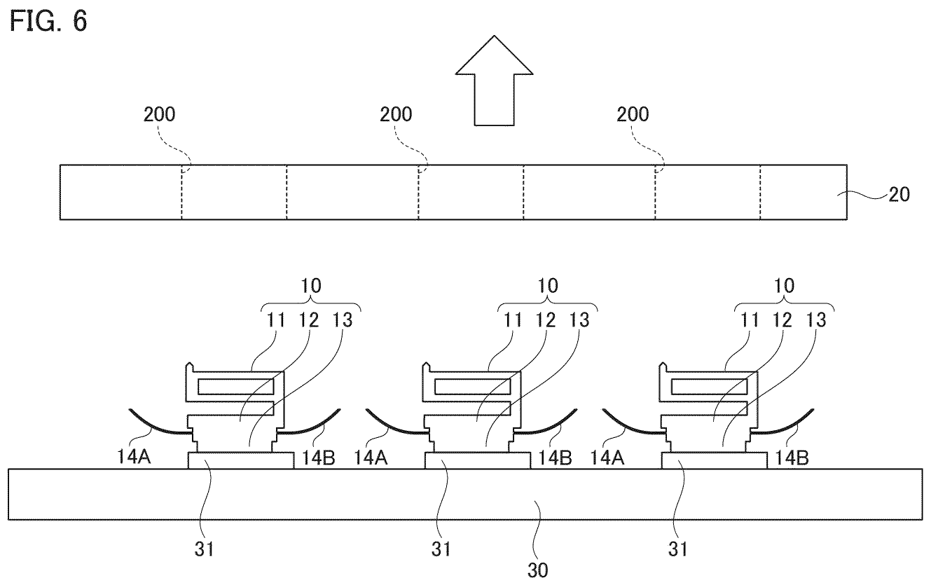

After the probe 10 is joined to the circuit board 30, the guide plate 20 is removed from the probe 10 in step S40 in FIG. 4, as illustrated in FIG. 6.

Then, in step S50, an inspection is made as to whether the probe 10 is joined normally to the circuit board 30. For example, the inspection is made as to whether the probe 10 is joined in a straight manner to a predetermined joint region of the circuit board 30 using camera photographing or the like. If there is a defect in the probe 10 joined to the circuit board 30, the process proceeds to step S55 to correct a joining state of the probe 10. After that, the process returns to step S50.

If there is no problem in joining the probe 10 to the circuit board 30 in step S50, the process ends. Thus, the process of joining the probe 10 to the circuit board 30 is completed.

In order to accurately inspect an object to be inspected using the electrical connection device in which the plurality of probes 10 are joined to the circuit board 30, the positions of the contact portions 113 of the probes 10 are required to be aligned with high accuracy. However, if the circuit board 30 is warped or distorted, the positions of the contact portions 113 of the probes may vary.

When the probe 10 is joined to the circuit board 30, in a state where the joint portion 13 is in contact with the circuit board 30, the tension generating section 14, which is elastically deformable in the first direction D1, contacts the first main surface 201 of the guide plate 20, thereby applying pressure to the first main surface 201. Therefore, when the probe 10 held by the guide plate 20 is brought close to the circuit board 30 in the first direction D1, and the joint portion 13 is brought into contact with the circuit board 30, the warpage and strain generated in the circuit board 30 are absorbed due to deformation of the tension generating section 14. As a result, a plurality of the probes 10 can be joined to the circuit board 30 with the positions of the contact portions 113 aligned with high accuracy.

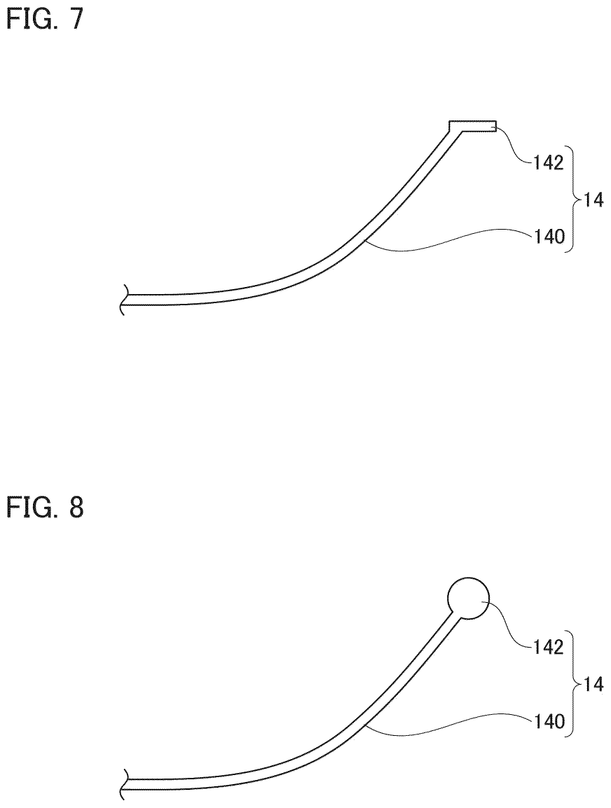

The second end 142 of the tension generating section 14 can be configured in any shape. For example, the shape of the second end 142 may be configured so that it is smoothly movable on the first main surface 201. For example, the second end 142 may be planar, as illustrated in FIG. 7. Alternatively, the second end 142 may be spherical, as illustrated in FIG. 8.

The tension generating section 14, included in the probe 10 according to the embodiment, is elastically deformable, and contacts the guide plate 20. Therefore, with the probes 10 according to the embodiment, the plurality of probes 10 can be attached to the circuit board 30 with the positions of the contact portions 113 aligned, even if the circuit board 30 is warped or distorted. The flexibility of the tension generating section 14 is set within a range within which the magnitude of the warpage and strain of the circuit board 30 can be absorbed.

### OTHER EMBODIMENTS

The present invention has been described in terms of embodiments as described above. However, it should not be understood that the descriptions and drawings which form part of this disclosure are intended to limit the invention. Various alternative embodiments, examples and operation techniques will be apparent to those skilled in the art from this disclosure.

The tension generating section 14 extending from the support portion 12 in the second direction D2 is described in the above as an example. However, the tension generating section 14 may extend in a direction intersecting the second direction D2. The direction in which the tension generating section 14 extends can be set according to the position of another adjacent probe 10.

The tension generating section 14 in the shape of a plate is described above as an example. However, any shape of the tension generating section 14 can be selected as long as the tension generating section 14 is elastically deformable in the first direction D1. For example, the cross section of the main body portion 140 in the extending direction may be circular, or polygonal, such as rectangular.

As described above, the present invention naturally includes various embodiments which are not described herein. Therefore, the technical scope of the present invention is defined only by matters specifying the invention according to the claims that are reasonable from the description above.

What is claimed is:

1. A probe used for inspection of an object to be inspected, comprising:
an arm portion including a fixed end and a free end, with a contact portion at a tip of the free end protruding in a first direction in a cantilever structure;
a support portion connected to the arm portion at the fixed end;
a joint portion connected to the support portion in a region where the support portion is separated from a region connected to the fixed end; and
a tension generating section including a first end connected to the support portion, and a second end located closer to the contact portion than the first end in the first direction, and that is separated from the support portion, the tension generating section being elastically deformable so that a position of the second end varies in the first direction.

2. The probe according to claim 1, wherein the tension generating section is in the shape of an arc bulging in the first direction.

3. The probe according to claim 1, wherein the second end of the tension generating section is planar.

4. The probe according to claim 1, wherein the second end of the tension generating section is spherical.

5. The probe according to claim 1, wherein:
the probe has a shape in which the joint portion is exposed outside a guide plate while being inserted into a through hole penetrating the guide plate, and
a shape of the tension generating section is provided so that the second end contacts a main surface of the guide plate where the through hole is formed, and pressure is applied to the main surface by the tension generating section.

6. A method of manufacturing an electrical connection device used for inspection of an object to be inspected, comprising:
preparing a probe, the probe comprising:
an arm portion including a fixed end and a free end, with a contact portion at a tip of the free end protruding in a first direction in a cantilever structure,
a support portion connected to the arm portion at the fixed end,
a joint portion connected to the support portion in a region where the support portion is separated from a region connected to the fixed end, and
a tension generating section including a first end connected to the support portion, and a second end located closer to the contact portion than the first end in the first direction, and that is separated from the support portion, the tension generating section being elastically deformable so that the position of the second end varies in the first direction;
preparing a guide plate in which a through hole is formed, the through hole penetrating from a first main surface to a second main surface facing in a direction opposite to the first main surface;
inserting the probe into the through hole of the guide plate;
holding the probe by the guide plate in a state where the joint portion is exposed outside the guide plate and the second end contacts the guide plate; and
joining the joint portion of the probe held by the guide plate to a circuit board.
